(19) United States
(12) Patent Application Publication
(10) Pub. No.: US 2025/0107325 A1
(43) Pub. Date: Mar. 27, 2025

(54) ORGANIC LIGHT-EMITTING DEVICE, PREPARATION METHOD, AND DISPLAY PANEL

(71) Applicant: HKC CORPORATION LIMITED, Shenzhen (CN)

(72) Inventors: ZHENGTAO ZHANG, Shenzhen (CN); Yaohui Qin, Shenzhen (CN); Kelin Wen, Shenzhen (CN); Lang Liu, Shenzhen (CN); Yulong Sun, Shenzhen (CN); Haijiang Yuan, Shenzhen (CN)

(21) Appl. No.: 18/889,415

(22) Filed: Sep. 19, 2024

(30) Foreign Application Priority Data
Sep. 27, 2023 (CN) 202311254617.1

(51) Int. Cl. H10K 50/858; H10K 50/165; H10K 71/00; H10K 102/00

(52) U.S. Cl. CPC H10K 50/858; H10K 50/165; H10K 71/811; H10K 2102/331

(57) ABSTRACT

An organic light-emitting device, a preparation method, and a display panel are disclosed. The organic light-emitting device is formed on a glass substrate. The organic light-emitting device includes a first electrode, a second electrode, and an organic light-emitting layer disposed between the second and the first electrode. A first light extraction layer is disposed between the first electrode and the glass substrate. The first light extraction layer is formed by dielectric nanoparticles. The side of the first light extraction layer facing towards the organic light-emitting layer has a relatively rough surface. Light is extracted from the organic light-emitting layer by the dielectric nanoparticles. The rough surface formed by the dielectric nanoparticles has a relatively greater ability to scatter more light. The dielectric nanoparticles are inserted into the glass substrate and extract light captured in the organic light-emitting layer, thus improving the light extraction efficiency of the organic light-emitting device.

### CROSS-REFERENCE TO RELATED APPLICATIONS

This application claims the priority and benefit of Chinese patent application number 2023112546171, titled “Organic Light-emitting Device, Preparation Method, and Display Panel” and filed Sep. 27, 2023 with China National Intellectual Property Administration, the entire contents of which are incorporated herein by reference.

### TECHNICAL FIELD

This application relates to the field of display technology, and more particularly relates to an organic light-emitting device, a preparation method, and a display panel.

### BACKGROUND

The description provided in this section is intended for the mere purpose of providing background information related to the present application but doesn't necessarily constitute prior art.

In recent years, organic light-emitting devices (OLEDs) that utilize organic electroluminescence (EL) materials to achieve high efficiency, long life, and full-color emission have been intensively researched and developed. With the continuous development of technology, OLED display panels are used in more and more applications, such as smartphones, monitors, and televisions (TVs).

Since there is no backlight unit, OLED display panels have many advantages over LCD display panels. For example, OLED display panels are thinner, lighter, and can be more flexible than LCD panels. In addition, organic light-emitting devices (OLEDs) have translucent properties and bidirectional emission capabilities, giving them high contrast and relatively wide viewing angles. However, the organic light-emitting devices of OLED display panels may have different internal light-emitting mechanisms, where a large amount of light loss causes deviation in the display effect. Therefore, improving the light extraction rate of organic light-emitting devices has become an urgent problem to be solved.

### SUMMARY

It is therefore one purpose of this application to provide an organic light-emitting device, a preparation method thereof, and a display panel with an improved light extraction efficiency.

This application discloses an organic light-emitting device. The organic light-emitting device is formed on a glass substrate. The organic light-emitting device includes a first electrode, a second electrode, and an organic light-emitting layer disposed between the second electrode and the first electrode. There is disposed a first light extraction layer between the first electrode and the glass substrate. The first light extraction layer is formed by dielectric nanoparticles. The side of the first light extraction layer facing the organic light-emitting layer has a relatively rough surface.

In some embodiments, the dielectric nanoparticle is a silicon dioxide dielectric nanoparticle. The entire first light extraction layer is fixed onto the side of the first electrode facing away from the organic light-emitting layer.

In some embodiments, a second light extraction layer is formed on the side of the glass substrate facing away from the organic light-emitting layer. The second light extraction layer has alternate concave and convex portions. The first light extraction layer is disposed in positions corresponding to the concave portions of the second light extraction layer and portions of the first light extraction layer corresponding to the convex portions of the second light extraction layer are hollowed out.

In some embodiments, a third light extraction layer is disposed between the first light extraction layer and the organic light-emitting layer. The third light extraction layer includes a recessed portion and a protruding portion that are alternately arranged at intervals. A refractive index of the third light extraction layer is smaller than the refractive index of the organic light-emitting layer and the refractive index of the first electrode. The first light extraction layer is disposed to only correspond to the recessed portion of the third light extraction layer.

In some embodiments, in the direction from the first electrode toward the second electrode, the organic light-emitting layer includes a hole injection layer, a hole transport layer, an organic light-emitting material layer, an electron transport layer, and an electron injection layer that are arranged in sequence. A first silver nanoparticles and a second silver nanoparticle of different shapes are disposed in the electron transport layer.

In some embodiments, the first silver nanoparticle is spherical, and the second silver nanoparticle is rod-shaped. The first silver nanoparticle and the second silver nanoparticle are alternately arranged at intervals. The preset distance between the first silver nanoparticle and the second silver nanoparticle adjacent to each other is d, d≥2r, where r is a radius value of the spherical first nanoparticle.

This application further discloses a method for preparing an organic light-emitting device, which is used to prepare an organic light-emitting device. The organic light-emitting device is formed on a glass substrate. The organic light-emitting device includes a first electrode, a second electrode, and an organic light-emitting layer disposed between the second electrode and the first electrode. A first light extraction layer is disposed between the first electrode and the glass substrate. The first light extraction layer is formed by dielectric nanoparticles. The first light extraction layer has a relatively rough surface on the side facing towards the organic light-emitting layer. The preparation method includes the following operations:

providing a glass substrate;

depositing silicon dioxide to prepare a target, fixing it onto the electrode, evacuating to create a vacuum, and filling in a preset concentration of argon gas, applying a preset voltage between the second electrode and the first electrode so that the atoms on the target surface escape due to collision thus producing target atoms that are deposited on the glass substrate to form the first light extraction layer; and

preparing the first electrode, the organic light-emitting layer and the second electrode in sequence;

wherein the side of the first light extraction layer facing the organic light-emitting layer has a relatively rough surface.

In some embodiments, the preparation method of the glass substrate in the operation of providing a glass substrate includes the following operations:

polishing the glass substrate surface, coating a protective mask on the polished surface, and then spin-coating a photoresist with a preset thickness;

performing pre-baking, exposure, development, using a corrosive liquid to remove the film layer on the exposed parts of the pattern, thereafter cleaning the surface and perform film hardening treatment, and performing etching after film hardening; and

cleaning the glass and removing the photoresist after etching is completed to obtain a single-curved-surface glass substrate;

wherein according to the need for the glass substrate to be concave on one side to form a hemispherical curved surface, an etchant is prepared for etching, and setting the etching parameters, where the film hardening temperature is 100-140° C., and the temperature is kept constant for 3-5 hours;

wherein the operation of depositing silicon dioxide to prepare a target, fixing it onto the a electrode, evacuating to create a vacuum, and filling in a preset concentration of argon gas, applying a preset voltage between the second electrode and the first electrode so that the atoms on the target surface escape due to collision thus producing target atoms that are deposited on the glass substrate to form the first light extraction layer includes:

placing on the glass substrate a mold that is hollowed out at positions corresponding to the protruding portions of the glass substrate; and

depositing silicon dioxide to prepare a target, fixing it onto the first electrode, evacuating, and rushing in a preset concentration of argon gas, applying a preset voltage between the second electrode and the first electrode, so that the atoms on the target surface escape due to collision, forming the target atoms that are deposited on the glass substrate to form the first light extraction layer corresponding only to the protrusions.

In some embodiments, the preparation method of the organic light-emitting layer includes the following operations:

sequentially forming a hole injection layer, a hole transport layer, an organic light-emitting material layer, and an electron transport layer on the first electrode;

preparing a first silver nanoparticle and a second silver nanoparticle by controlling temperature, PH value, concentration, etc. using a hydrothermal method, and then using an electrospinning process to embed the first silver nanoparticle and the second silver nanoparticle into the electron transport layer; and

forming an electron injection layer and a second electrode on the electron transport layer embedded with the first silver nanoparticle and the second silver nanoparticle.

This application further discloses a display panel. The display panel includes an organic light-emitting device. The display panel further includes a plurality of scan lines and a plurality of data lines. Each organic light-emitting device is connected to the respective scan line and the respective data line. The organic light-emitting device includes a first electrode, a second electrode, and an organic light-emitting layer disposed between the second electrode and the first electrode. A first light extraction layer is disposed between the first electrode and the glass substrate. The first light extraction layer is formed by dielectric nanoparticles. The first light extraction layer has a relatively rough surface on the side facing towards the organic light-emitting layer.

This application discloses an organic light-emitting device, a preparation method, and a display panel. The organic light-emitting device is formed on a glass substrate. The organic light-emitting device includes a first electrode, a second electrode, and an organic light-emitting layer disposed between the second electrode and the first electrode. There is a disposed first light extraction layer between the first electrode and the glass substrate. The first light extraction layer is formed by dielectric nanoparticles. The side of the first light extraction layer facing the organic light-emitting layer has a relatively rough surface.

### BRIEF DESCRIPTION OF DRAWINGS

The accompanying drawings are used to provide a further understanding of the embodiments according to the present application, and constitute a part of the specification. They are used to illustrate the embodiments according to the present application, and explain the principle of the present application in conjunction with the text description. Apparently, the drawings in the following description merely represent some embodiments of the present disclosure, and for those having ordinary skill in the art, other drawings may also be obtained based on these drawings without investing creative efforts. A brief description of the accompanying drawings is provided as follows.

FIG. 1 is a schematic diagram of an organic light-emitting device according to a first embodiment of the present application.

FIG. 2 is a schematic diagram of an organic light-emitting device according to a second embodiment of the present application.

FIG. 3 is a schematic diagram of another organic light-emitting device according to the second embodiment of the present application.

FIG. 4 is a schematic diagram of an organic light-emitting device according to a third embodiment of the present application.

FIG. 5 is a schematic diagram of another organic light-emitting device according to the third embodiment of the present application.

FIG. 6 is a schematic diagram of an organic light-emitting device according to a fourth embodiment of the present application.

FIG. 7 is a schematic flow chart of a preparation method of an organic light-emitting device according to a fifth embodiment of the present application.

FIG. 8 is a schematic flow chart of a preparation method of an organic light-emitting device according to a sixth embodiment of the present application.

FIG. 9 is a schematic flow chart of a preparation method of an organic light-emitting device according to a seventh embodiment of the present application.

FIG. 10 is a schematic diagram of a display panel according to an eighth embodiment of the present application.

In the drawings: 100, display panel; 110, data line; 120, scan line; 200, organic light-emitting device; 210, first electrode; 220, second electrode; 230, organic light-emitting layer; 231, hole injection layer; 232, hole transport layer; 233, organic light-emitting material layer; 234, electron transport layer; 235, electron injection layer; 240, first light extraction layer; 241, dielectric nanoparticle; 242, hollow; 250, second light extraction layer; 260, third light extraction layer; 261, recessed portion; 262, protruding portion; 270, first silver nanoparticle; 280, second silver nanoparticle; 300, glass substrate.

### DETAILED DESCRIPTION OF EMBODIMENTS

It would be understood that the terms used herein, the specific structures and function details disclosed herein are intended for the mere purposes of describing specific embodiments and are representative. However, this application may be implemented in many alternative forms and should not be construed as being limited to the embodiments set forth herein.

As used herein, terms “first”, “second”, or the like are merely used for illustrative purposes, and shall not be construed as indicating relative importance or implicitly indicating the number of technical features specified. Thus, unless otherwise specified, the features defined by “first” and “second” may explicitly or implicitly include one or more of such features. Terms “multiple”, “a plurality of”, and the like mean two or more. Term “comprising”, “including”, and any variants thereof mean non-exclusive inclusion, so that one or more other features, integers, steps, operations, units, components, and/or combinations thereof may be present or added.

In addition, terms “center”, “transverse”, “up”, “down”, “left”, “right”, “vertical”, “horizontal”, “top”, “bottom”, “inside”, “outside”, or the like are used to indicate orientational or relative positional relationships based on those illustrated in the drawings. They are merely intended for simplifying the description of the present disclosure, rather than indicating or implying that the device or element referred to must have a particular orientation or be constructed and operate in a particular orientation. Therefore, these terms are not to be construed as restricting the present disclosure.

Furthermore, as used herein, terms “installed on”, “mounted on”, “connected to”, “coupled to”, “connected with”, and “coupled with” should be understood in a broad sense unless otherwise specified and defined. For example, they may indicate a fixed connection, a detachable connection, or an integral connection. They may denote a mechanical connection, or an electrical connection. They may denote a direct connection, a connection through an intermediate, or an internal connection between two elements. For those of ordinary skill in the art, the specific meanings of the above terms as used in the present application can be understood depending on specific contexts.

Hereinafter this application will be described in further detail with reference to the accompanying drawings and some optional embodiments.

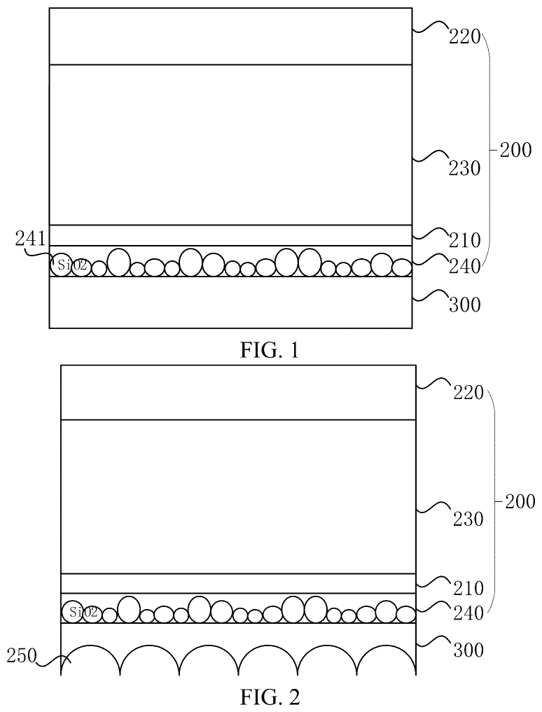

As shown in FIG. 1, as an organic light-emitting device according to a first embodiment of the present application, the organic light-emitting device 200 is formed on a glass substrate 300. The organic light-emitting device 200 includes a first electrode 210, a second electrode 220, and an organic light-emitting layer 230 disposed between the second electrode 220 and the first electrode 210. Generally, the first electrode 210 is an anode, which is made of indium zinc oxide ITO. The second electrode 220 is a cathode, which is made of a metal. The organic light-emitting device 200 includes a first light extraction layer 240, which is disposed between the first electrode 210 and the glass substrate 300. The first light extraction layer 240 is comprised of dielectric nanoparticles 241. The side of the first light extraction layer 240 facing the organic light-emitting layer 230 is a relatively rough surface. In other words, a layer of dielectric nanoparticles 241 is added to the glass substrate 300. The relatively rough surface formed by the dielectric nanoparticles 241 may cause scattering, thereby coupling out the emitted light from the waveguide mode. This means that dielectric nanoparticles may be better suited to extracting light from devices, for they have a greater ability to scatter more light to break the waveguide caused by the index contrast between the first electrode 210 (ITO layer) and glass. By alleviating the light loss in the waveguide mode, more power can be extracted from the organic light-emitting layer 230 into the glass substrate, thereby improving the light extraction rate of the organic light-emitting device 200.

Further, the dielectric nanoparticle 241 may be a silicon dioxide (SiO₂) dielectric nanoparticle. The entire first light extraction layer 240 is fixed onto the side of the first electrode 210 facing away from the organic light-emitting layer 230. Specifically, the conduction band in the density of states of SiO₂ is located on the right side of the Fermi level and does not pass through the Fermi level, so that the system exhibits insulating properties. In addition, the insulating properties are also reflected in the energy band, so that dielectric nanoparticle 241 does not exhibit dipolar plasmon resonance and has a positive dielectric constant in the visible light range. Furthermore, part of the incident energy is not absorbed by the SiO₂ dielectric nanoparticles and is lost in the form of Joule heating. That is, the dielectric nanoparticle 241 does not have dissipative characteristics within the spectral range of the organic light-emitting device (OLED).

The reason why SiO₂ dielectric nanoparticles are chosen is because the preparation cost is relatively low. In order to better improve scattering to improve the light extraction efficiency, spherical SiO₂ dielectric nanoparticles are selected. When the distance between dielectric nanoparticle particles increases from 0 nm, the resonance wavelength shifts to the left. As the interparticle distance increases, the wave peak undergoes a blue shift and decreases in intensity, indicating that the coupling effect between the two spherical nanoparticles weakens. Furthermore, the decrease in the intensity of these peaks with the distance between dielectric nanoparticles reflects the attenuation of the field distribution between particles. Therefore, SiO₂ dielectric nanoparticles are closely packed with no interparticle spacing. SiO₂ dielectric nanoparticles are randomly arranged, and the surface will form a structure like a rough surface, making the light refraction intensity greater. This means that SiO₂ dielectric nanoparticles have a greater ability to scatter more light, so that the light extraction efficiency of the OLED is improved.

In addition, the water vapor penetrating into the OLED may cause condensation inside the OLED, thus causing electricity leakage and short circuit in the OLED, and in severe cases, the OLED display panel may be burned. In addition, a small amount of water vapor penetrating into the OLED may also cause the water vapor to react with internal materials, causing local purpling or powdering problems in the display. Therefore, SiO₂ dielectric nanoparticles are selected as the buffer layer between the glass substrate 300 and the ITO layer. The SiO₂ dielectric nanoparticles can lengthen the traveling route of water vapor, help block the penetration of water vapor, thus effectively preventing the OLED display panel from turning purple or powdery.

As shown in FIG. 2, the organic light-emitting device according to the second embodiment of the present application is a further refinement of the above-mentioned first embodiment. Considering that there may still be light loss after the light passes through the first light extraction layer 240, a second light extraction layer 250 is formed on the side of the glass substrate 300 facing away from the organic light-emitting layer 230, where the second light extraction layer 250 is designed to have alternate concave and convex portions.

Since the refractive index of the glass substrate 300 and that of the air do not match, the OLED may undergo substrate mode loss at the interface between the glass substrate 300 and the air, causing a part of the light to be lost at the interface between the glass substrate 300 and the air. This part of the light loss accounts for 30% of the total light loss in organic light-emitting devices. In order to further improve the light extraction efficiency of OLED, a semicircular grating structure is constructed on the glass layer of the grating single-layer OLED to break the internal reflection at the interface between the glass layer and the air thereby improving the light extraction efficiency of OLED. The semicircular grating structure may be seen as a microlens array added to the back of the substrate, so that part of the light lost due to total reflection is extracted. This semicircular wavy surface effectively weakens the light loss of the substrate mode, allowing more photons to be extracted from the substrate mode, improving the light extraction efficiency.

Furthermore, considering that recesses are conducive to scattering, in order to reduce the preparation time of the first light extraction layer 240 and the preparation materials of the light extraction layer, a hollow 242 may be defined at the recess in the first light extraction layer 240 corresponding to the second light extraction layer 250, as shown in FIG. 3.

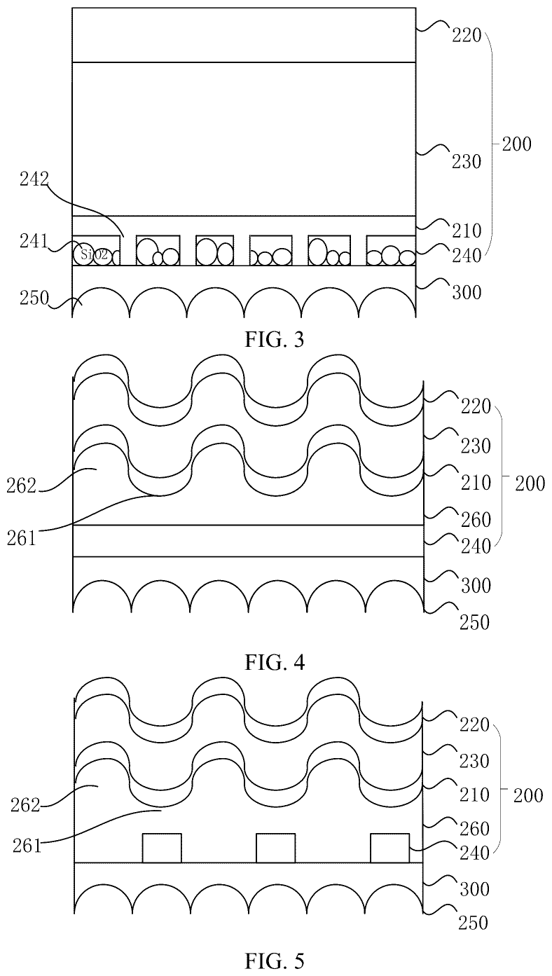

As shown in FIG. 4, the organic light-emitting device according to a third embodiment of the present application is different from the above-mentioned embodiment in that a third light extraction layer 260 is disposed between the first light extraction layer 240 and the organic light-emitting layer 230. One side of the third light extraction layer 260 is connected to the first light extraction layer 240, and the other side is connected to the first electrode 210. Alternatively, one side of the third light extraction layer 260 is connected to the first electrode 210, and the other side is connected to the organic light-emitting layer 230. The third light extraction layer 260 includes a plurality of recessed portions 261 and protruding portions 262 arranged at intervals. The organic light-emitting layer 230 is disposed on the third light extraction layer 260 to form a microlens-shaped curved surface. Part of the light incident on the glass substrate is reflected in the same state as the polarization axis of the polarizing plate by applying MLA and microlenses. Therefore, the reflectivity of the organic light-emitting device 200 can be improved. Furthermore, the light generated in the organic light-emitting layer 230 passes through the glass substrate to reach the polarizing plate, and is reflected again in the polarizing plate. Therefore, the light path is shifted in the direction of the glass substrate to improve the light extraction rate.

Further, the refractive index of the third light extraction layer 260 is smaller than the refractive index of the organic light-emitting layer 230 and the refractive index of the first electrode 210. Generally, the refractive index of the glass substrate 300 and the third light extraction layer 260 is about 1.5, while the refractive index of the first electrode 210 of the organic light-emitting device 200 and the refractive index of the organic light-emitting layer 230 may be 1.7 to 2.0. In this case, part of the light emitted from the organic light-emitting layer 230 is reflected by the second electrode 220. Therefore, the light path is deflected in the direction of the first electrode 210 and the remaining part is reflected in the direction of the first electrode 210. That is, most of the light generated by the organic light-emitting layer 230 is guided to the direction of the first electrode 210.

Since the refractive index of the organic light-emitting layer 230 and the refractive index of the first electrode 210 are almost the same as each other, the path of light generated from the organic light-emitting layer 230 does not change at the interface between the organic light-emitting layer 230 and the first electrode 210. At the same time, in the light passing through the first electrode 210, due to the difference in refractive index between the first electrode 210 and the third light extraction layer 260, the light incident at a threshold angle or a larger angle may be totally reflected at the interface between the first electrode 210 and the third light extraction layer 260.

Further, as shown in FIG. 5, the first light extraction layer 240 is disposed only corresponding to the recessed portion 261 of the third light extraction layer 260. Considering that after light passes through the third light extraction layer 260, the light in the recessed portion 261 of the third light extraction layer 260 easily passes through thus causing loss, while the protruding portion 262 is prone to reflection, which can increase the light extraction rate and reduce loss, so the first light extraction layer 240 may be disposed corresponding to the recessed portion 261 of the third light extraction layer 260, and the first light extraction layer 240 may not be arranged at other positions, thereby reducing the preparation time and materials required for the first light extraction layer 240.

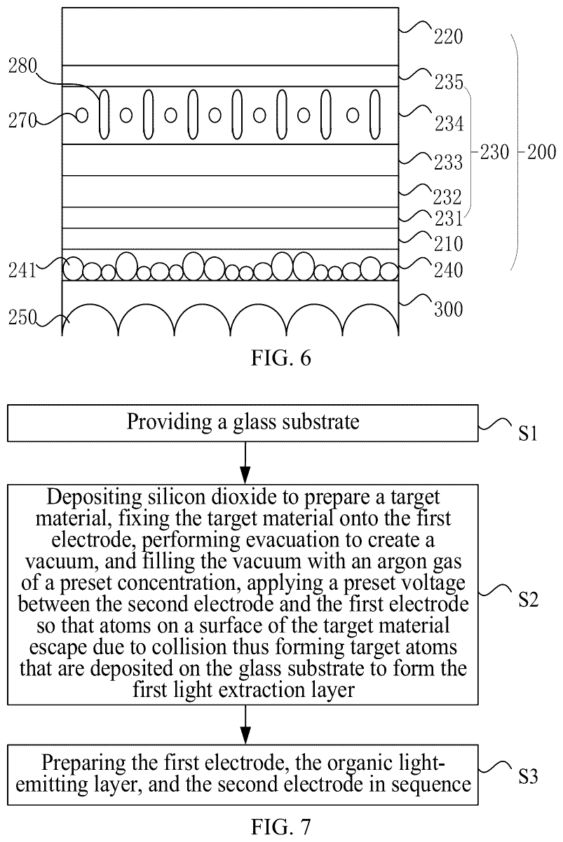

As shown in FIG. 6, the organic light-emitting device according to a fourth embodiment of the present application is a further refinement and improvement based on any of the above embodiments. In the direction from the first electrode 210 to the second electrode 220, the organic light-emitting layer 230 includes a hole injection layer 231, a hole transport layer 232, an organic light-emitting material layer 233, an electron transport layer 234 and electron injection layer 235 that are arranged in sequence. A first silver nanoparticle 270 and a second silver nanoparticle 280 of different shapes are arranged in the electron transport layer 234. The first silver nanoparticle 270 and the second silver nanoparticle 280 are embedded in the electron transport layer 234. The first silver nanoparticle 270 is in the shape of a sphere, and the second silver nanoparticle 280 is in the shape of a rod. The first silver nanoparticle 270 and the second silver nanoparticle 280 are alternately arranged at intervals. The preset distance between the first silver nanoparticle 270 and the second silver nanoparticle 280 that are adjacent to each other is d, d≥2r, where r is a radius value of the spherical first silver nanoparticle 270. The center points of the spherical first silver nanoparticle 270 and the rod-shaped second silver nanoparticle 280 lies on a same horizontal line and they are arranged regularly. However, due to the influence of equipment or material resistance during the embedding process, the two nanoparticles are not regularly arranged, and the angles with the horizontal line at the center point are different. Generally, the angle between each of the second silver nanoparticles 280 on both sides and the horizontal line is between 70 degrees and 90 degrees, and the angle between the second silver nanoparticle 280 in the middle and the horizontal line is between 60 degrees and 90 degrees.

Specifically, when the organic light-emitting layer 230 emits light that has effective wavelength coupling with the plasmon resonance, the light extraction efficiency of the electron transport layer 234 will be improved, and the plasmon resonance is effectively affected by changing the combination, shapes, sizes, and surrounding media of the first silver nanoparticle 270 and the second silver nanoparticle 280 in the electron transport layer 234. Usually, the gap distance between adjacent first silver nanoparticle and second silver nanoparticle is considered to be twice the radius of the first silver nanoparticle to induce photon plasmon resonance. The surface plasmon band of the rod-shaped second silver nanoparticle is divided into two bands: the light absorption and scattering corresponding to the longitudinal plasmon band along the long axis of the rod and the light absorption and scattering corresponding to the transverse plasmon band along the short axis of the rod. The relatively smaller first silver nanoparticle has less light scattering and light absorption than the relatively larger second silver nanoparticle. Although the Ag nanostructure added with the first silver nanoparticle and the second silver nanoparticle also absorbs light, the proportion of light absorbed will be lower than that without adding the nanostructure, and the loss will be greatly reduced. Furthermore, the mode of inserting the mixed spherical and rod-shaped nanostructures is used to alleviate the loss of surface plasmon effect. Assume that a completely lossless light beam from the organic light-emitting layer 230 is transmitted to the electron transport layer 234, and half of the light is lost in the electron transport layer 234. Then after adding Ag nanostructure, the Ag nanostructure will become a secondary light source, allowing the light to be used twice. The light scattering produced by nanoparticles can make the effective use of light greater than 50%, thereby extracting photons trapped in the substrate or waveguide mode, which improves the light extraction efficiency.

To sum up, this application focuses on improving light extraction efficiency from three aspects: the substrate mode inside the OLED, the waveguide mode between the first electrode 210 and the organic layer, and the plasmon mode.

As shown in FIG. 7, as a fifth embodiment of the present application, the present application further discloses a method for preparing an organic light-emitting device, which is used to prepare the organic light-emitting device described in any of the above embodiments. The preparation method includes the following operations: .

S1: providing a glass substrate;

S2: depositing silicon dioxide to prepare a target material, fixing it onto the first electrode, evacuating to create a vacuum, and filling it with a preset concentration of argon gas, applying a preset voltage between the second electrode and the first electrode, so that the atoms on the target surface escape due to collusion thus producing target atoms deposited on the glass substrate to form the first light extraction layer; and

S3: preparing a first electrode, an organic light-emitting layer, and a second electrode in sequence;

Referring to FIGS. 1, 2, and 7, the side of the first light extraction layer 240 facing the organic light-emitting layer 230 has a relatively rough surface. Specifically, SiO₂ is deposited to prepare a target material which is fixed onto the cathode. After the device is evacuated to a vacuum, a certain amount of argon gas is filled in, and a voltage of several thousand volts is applied to the cathode and anode. The positive ions generated by the discharge fly toward the cathode under the action of the electric field, collide with the atoms on the target surface, and the target atoms escape from the target surface due to the collision and are deposited on the substrate to form a SiO₂ nanofilm layer.

The first light extraction layer 240 is formed between the glass substrate 300 and the organic light-emitting layer 230. The rough surface formed by the dielectric nanoparticles 241 in the first light extraction layer 240 causes scattering, thereby coupling out the emitted light from the waveguide mode. The dielectric nanoparticle 241 does not exhibit dipole plasmon resonance. The dielectric nanoparticles 241 may be better suited for extracting light from devices, for they have a relatively greater ability to scatter more light, thus breaking the waveguide caused by the index contrast between the first electrode 210 (ITO layer) and the glass. By alleviating the light loss in the waveguide mode, more power can be extracted from the organic layer into the glass substrate, thereby improving the light extraction rate of the organic light-emitting device 200.

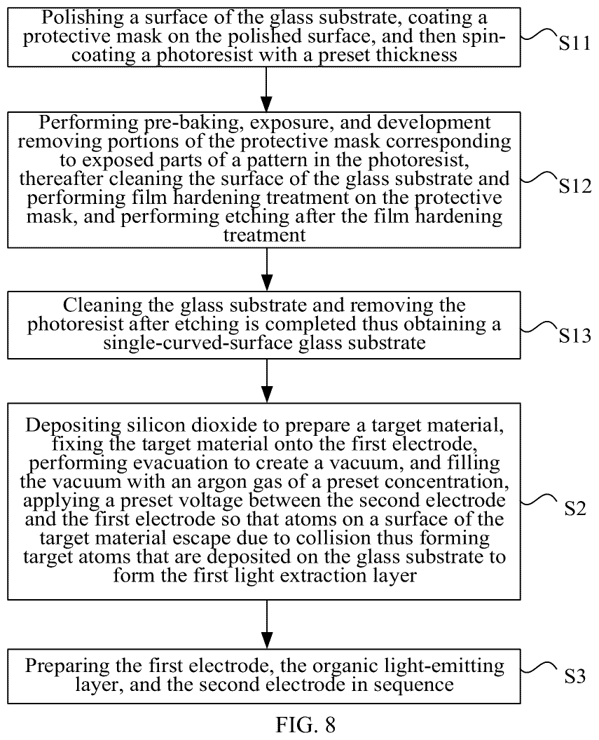

As shown in FIG. 8, as a sixth example of the present application, it is a further refinement and improvement based on the above-mentioned fifth embodiment, and is also a preparation method provided for the organic light-emitting device of the above-mentioned second embodiment. The preparation method of the glass substrate in operation S1 includes the following operations.

S11: polishing the glass substrate surface, applying a protective mask on the polished surface, and then spin-coating a photoresist with a preset thickness;

S12: performing pre-baking, exposure, and development, and using a corrosive liquid to remove the portions of the protective mask corresponding to exposed parts of the pattern in the photoresist; thereafter, cleaning the surface of the glass substrate and performing film hardening treatment on the protective mask; and performing etching after the film hardening is performed;

S13: perform etching, then cleaning the glass and removing the photoresist to obtain a single-curved-surface glass substrate;

According to the need for a single concave surface on the glass substrate to form a hemispherical curved surface, the etchant is prepared for etching and the etching parameters are set. The etching parameters include an etching temperature and an etching speed. The temperature for hardening the film is 100-140° C., and the temperature is kept constant for 3-5 hours.

Further, the operation of depositing silicon dioxide to prepare a target material, fixing it onto the first electrode, evacuating to create a vacuum, and filling it with a preset concentration of argon gas, applying a preset voltage between the second electrode and the first electrode, so that the atoms on the target surface escape due to collision thus producing target atoms deposited on the glass substrate to form the first light extraction layer includes:

S21: placing on the glass substrate a mold that is hollowed out at positions corresponding to the protruding portions of the glass substrate; and

S22: depositing silicon dioxide to prepare a target, fixing it onto the first electrode, evacuating to create a vacuum, and filling in a preset concentration of argon gas, applying a preset voltage between the second electrode and the first electrode, so that the atoms on the target surface escape due to collision thus producing target atoms that are deposited on the glass substrate to form the first light extraction layer corresponding only to the protrusions.

That is, one may polish the surface of the glass substrate, apply a protective mask on the polished surface, and then spin-coat a little thickness of photoresist. After pre-baking at 100° C., exposure, and development, the exposed parts of the film in the pattern is removed using an etching liquid. Thereafter, one may clean the surface and perform hard film treatment. The film hardening temperature is 120° C. and is kept constant for 4 hours. After the film is hardened, etching will be carried out. According to the need for the glass to be concave on one side to form a hemispherical curved surface, the etchant is prepared for etching, and parameters such as the etching temperature and stirring speed are set. After the etching is completed, the glass is cleaned and the photoresist is removed to obtain a single-curved-surface glass substrate.

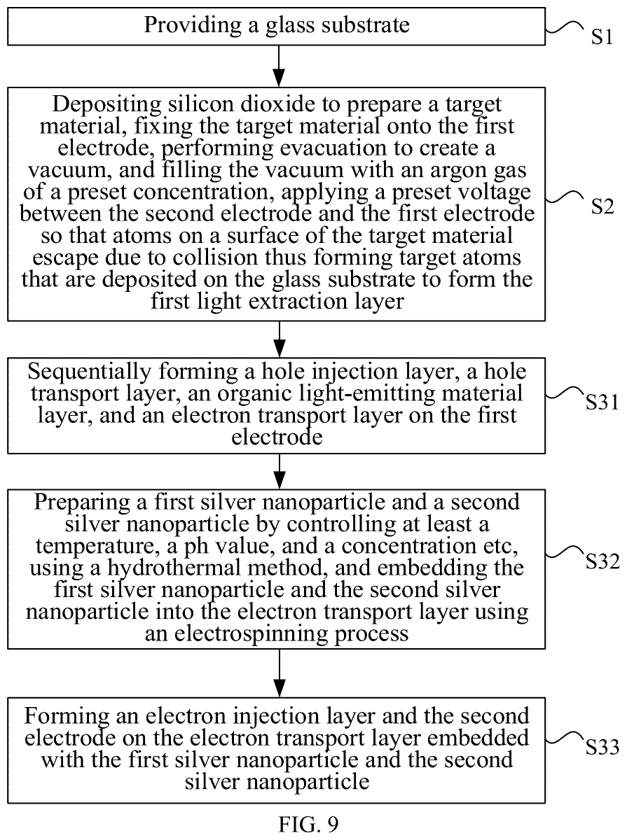

As shown in FIG. 9, as a seventh example of the present application, which is a further limitation of the above fifth or sixth embodiment, the preparation method of the organic light-emitting layer includes the following operations:

S31: forming a hole injection layer, a hole transport layer, an organic light-emitting material layer, and an electron transport layer in sequence on the first electrode;

S32: preparing a first silver nanoparticle and a second silver nanoparticle by controlling a temperature, a PH value, a concentration, etc. by hydrothermal method, and then using an electrospinning process to embed the first silver nanoparticle and the second silver nanoparticle into the electron transport layer; and

S33: forming an electron injection layer and a second electrode on the electron transport layer embedded with the first silver nanoparticle and the second silver nanoparticle.

Specifically, two different Ag nanoparticles, spherical and rod-shaped, were prepared by controlling the temperature, pH value, concentration, etc. through a hydrothermal method, and then the electrospinning process is used to embed the two different Ag nanoparticles into the electron transport layer. The electrospinning process includes embedment in two times. For the first time, the spherical first silver nanoparticle is embedded, starting from the edge of the electron transport layer, where the spacing parameter of the adjacent first silver nanoparticles is set to 6r. For the second time, the rod-shaped second silver nanoparticle is embedded, starting from 4r from the edge of the electron transport layer, where the parameter of the distance between adjacent second silver nanoparticle particles is set to 6r, so that finally the Ag nanostructures with alternately embedded spheres and rods are formed.

For the preparation of SiO₂ nanoparticles, it is required to strictly control the atmospheric pressure and the amount of argon gas introduced. Furthermore, if the target shooting time is too long, the film layer may be too thick, and if the target shooting time is too short, the coverage of the particles will be incomplete. Therefore, every condition needs to be precisely controlled during the preparation process to prevent low utilization of SiO₂ target materials and excessive costs. For the preparation of Ag nanoparticles, it is required to control the temperature difference of the solution in the autoclave to generate convection to form a supersaturated state thus precipitating Ag nanoparticles. The precipitated Ag nanocrystals have irregular shapes, and it is difficult to precipitate into spherical and rod shapes simultaneously. It is required to strictly control the reaction time and temperature separately to precipitate spheres or rods first, so the embedding is carried out in two times.

Referring to FIGS. 6 and 9, a completely lossless beam of light from the organic light-emitting layer 230 is transmitted to the electron transport layer 234, and half of the light is lost in the electron transport layer 234. The mode of inserting a mixture of spherical and rod-like nanostructures can improve surface plasmon effect losses. After the Ag nanostructure is formed, the Ag nanostructure will become a secondary light source, allowing the light to be used twice. At this time, the light scattering generated by the nanoparticles can make the effective use of light greater than 50%, thus extracting the photons trapped in the substrate or waveguide mode, which improves light extraction efficiency.

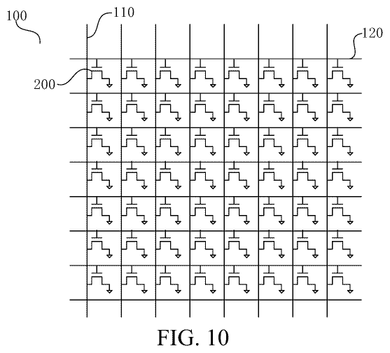

As shown in FIG. 10, as an eighth embodiment of the present application, a display panel 100 is disclosed. The display panel 100 includes the organic light-emitting device 200 as described in any of the above embodiments. The display panel 100 further includes a plurality of scan lines 120 and a plurality of data lines 110. Each organic light-emitting device 200 is connected to the respective scan line 120 and the respective data line 110.

It should be noted that the limitations of various operations involved in this solution will not be deemed to limit the order of the operations, provided that they do not affect the implementation of the specific solution, so that the operations written earlier may be executed earlier or they may also be executed later or even at the same time. As long as the solution can be implemented, they should all be regarded as falling in the scope of protection of this application.

It should be noted that the inventive concept of the present application can be formed into many embodiments, but the length of the application document is limited and so these embodiments cannot be enumerated one by one. The technical features can be arbitrarily combined to form a new embodiment, and the original technical effect may be enhanced after the various embodiments or technical features are combined.

The foregoing description is merely a further detailed description of the present application made with reference to some specific illustrative embodiments, and the specific implementations of the present application will not be construed to be limited to these illustrative embodiments. For those having ordinary skill in the technical field to which this application pertains, numerous simple deductions or substitutions may be made without departing from the concept of this application, which shall all be regarded as falling in the scope of protection of this application.

What is claimed is:

1. An organic light-emitting device, being formed on a glass substrate; wherein the organic light-emitting device comprises a first electrode, a second electrode, and an organic light-emitting layer disposed between the second electrode and the first electrode;
wherein there is disposed a first light extraction layer between the first electrode and the glass substrate; wherein the first light extraction layer is formed by dielectric nanoparticles; wherein a side of the first light extraction layer facing towards the organic light-emitting layer has a relatively rough surface.

2. The organic light-emitting device as recited in claim 1, wherein the dielectric nanoparticle is a silicon dioxide dielectric nanoparticle; wherein the entire first light extraction layer is fixed onto a side of the first electrode facing away from the organic light-emitting layer.

3. The organic light-emitting device as recited in claim 1, wherein there is formed a second light extraction layer on a side of the glass substrate facing away from the organic light-emitting layer;
wherein the second light extraction layer comprises alternately arranged concave and convex portions; wherein the first light extraction layer is disposed in positions corresponding to the concave portions of the second light extraction layer and wherein portions of the first light extraction layer corresponding to the convex portions of the second light extraction layer are hollowed out.

4. The organic light-emitting device as recited in claim 1, wherein there is disposed a third light extraction layer between the first light extraction layer and the first electrode;
wherein the third light extraction layer comprises a recessed portion and a protruding portion that are alternately arranged;
wherein the third light extraction layer has a refractive index that is less than a refractive index of the organic light-emitting layer and a refractive index of the first electrode;
wherein the first light extraction layer is disposed only in positions corresponding to the recessed portions of the third light extraction layer; wherein the recessed portion is recessed in a direction facing away from the organic light-emitting layer.

5. The organic light-emitting device as recited in claim 2, wherein in the direction from the first electrode toward the second electrode, the organic light-emitting layer comprises a hole injection layer, a hole transport layer, an organic light-emitting material layer, an electron transport layer, and an electron injection layer that are sequentially arranged;
wherein the electron transport layer comprises a first silver nanoparticle and a second silver nanoparticle of different shapes.

6. The organic light-emitting device as recited in claim 5, wherein the first silver nanoparticle is spherical, and the second silver nanoparticle is rod-shaped; wherein the first silver nanoparticle and the second silver nanoparticle are alternately arranged at intervals;
wherein a preset distance between the first silver nanoparticle and the second silver nanoparticle that are adjacent to each other is d, d≥2r, where r is a radius value of the spherical first nanoparticle.

7. The organic light-emitting device as recited in claim 1, wherein there is formed a microlens array on a surface of the glass substrate facing away from the organic light-emitting layer.

8. The organic light-emitting device as recited in claim 2, wherein there is formed a second light extraction layer on a side of the glass substrate facing away from the organic light-emitting layer; wherein the second light extraction layer comprises alternately arranged concave and convex portions; wherein the first light extraction layer is disposed in positions corresponding to the concave portions of the second light extraction layer and wherein portions of the first light extraction layer corresponding to the convex portions of the second light extraction layer are hollowed out.

9. The organic light-emitting device as recited in claim 3, wherein there is disposed a third light extraction layer between the first light extraction layer and the first electrode;
wherein the third light extraction layer comprises a recessed portion and a protruding portion that are alternately arranged;
wherein the third light extraction layer has a refractive index that is less than a refractive index of the organic light-emitting layer and a refractive index of the first electrode;
wherein the first light extraction layer is disposed only in positions corresponding to the recessed portions of the third light extraction layer; wherein the recessed portion is recessed in a direction facing away from the organic light-emitting layer.

10. The organic light-emitting device as recited in claim 4, wherein in the direction from the first electrode toward the second electrode, the organic light-emitting layer comprises a hole injection layer, a hole transport layer, an organic light-emitting material layer, an electron transport layer, and an electron injection layer that are sequentially arranged;
wherein the electron transport layer comprises a first silver nanoparticle and a second silver nanoparticle of different shapes.

11. The organic light-emitting device as recited in claim 6, wherein an angle measured from the second silver nanoparticle on each of both sides of the electron transport layer to a horizontal line lies in the range between 70 degrees and 90 degrees, and wherein an angle measured from the second silver nanoparticle in a middle area of the electron transport layer to the horizontal line lies in the range between 60 degrees and 90 degrees.

12. The organic light-emitting device as recited in claim 9, wherein a refractive index of each of the glass substrate and the third light extraction layer is substantially 1.5, and wherein a refractive index of the first electrode and a refractive index of the organic light-emitting layer of the organic light-emitting device each lie in the range between 1.7 and 2.0.

13. A method of preparing an organic light-emitting device, wherein the organic light-emitting device is formed on a glass substrate; wherein the organic light-emitting device comprises a first electrode, a second electrode, and an organic light-emitting layer disposed between the second electrode and the first electrode; wherein there is disposed a first light extraction layer between the first electrode and the glass substrate; wherein the first light extraction layer is formed by dielectric nanoparticles; wherein a side of the first light extraction layer facing towards the organic light-emitting layer has a rough surface; wherein the method comprises:
providing a glass substrate;
depositing silicon dioxide to prepare a target material, fixing the target material onto the first electrode, performing evacuation to create a vacuum, and filling the vacuum with an argon gas of a preset concentration, applying a preset voltage between the second electrode and the first electrode so that atoms on a surface of the target material escape due to collision thus forming target atoms that are deposited on the glass substrate to form the first light extraction layer; and
preparing the first electrode, the organic light-emitting layer, and the second electrode in sequence;
wherein the side of the first light extraction layer facing towards the organic light-emitting layer has a rough surface.

14. The method as recited in claim 13, wherein the operation of providing the glass substrate comprises:
polishing a surface of the glass substrate, coating a protective mask on the polished surface, and then spin-coating a photoresist with a preset thickness;
performing pre-baking, exposure, and development; removing portions of the protective mask corresponding to exposed parts of a pattern in the photoresist, thereafter cleaning the surface of the glass substrate and performing film hardening treatment on the protective mask, and performing etching after the film hardening treatment; and
cleaning the glass substrate and removing the photoresist after etching is completed thus obtaining a single-curved-surface glass substrate;
wherein according to a need for the glass substrate to be concave on one side to form a hemispherical curved surface, preparing an etchant for etching and setting etching parameters, wherein a film hardening temperature is set to 100-140° C., and the temperature is kept constant for 3-5 hours.

15. The method as recited in claim 13, wherein the operation of depositing silicon dioxide to prepare a target material, fixing the target material onto the first electrode, performing evacuation to create a vacuum, and filling the vacuum with an argon gas of a preset concentration, applying a preset voltage between the second electrode and the first electrode so that atoms on a surface of the target material escape due to collision thus producing target atoms that are deposited on the glass substrate to form the first light extraction layer comprises:
placing on the glass substrate a mold that is hollowed out at positions corresponding to protruding portions of the glass substrate; and
depositing silicon dioxide to prepare the target material, fixing the target material onto the first electrode, performing evacuation to create the vacuum, and filling the vacuum with the argon gas of the preset concentration, applying the preset voltage between the second electrode and the first electrode so that the atoms on the surface of the target material escape due to collision thus producing the target atoms that are deposited on the glass substrate to form the first light extraction layer corresponding only to the protruding portions of the glass substrate.

16. The method as recited in claim 13, wherein the organic light-emitting layer is prepared by the following operations:
sequentially forming a hole injection layer, a hole transport layer, an organic light-emitting material layer, and an electron transport layer on the first electrode;
preparing a first silver nanoparticle and a second silver nanoparticle by controlling at least a temperature, a PH value, and a concentration using a hydrothermal method, and embedding the first silver nanoparticle and the second silver nanoparticle into the electron transport layer using an electrospinning process; and
forming an electron injection layer and the second electrode on the electron transport layer embedded with the first silver nanoparticle and the second silver nanoparticle.

17. The method as recited in claim 16, wherein the operations of preparing a first silver nanoparticle and a second silver nanoparticle by controlling at least a temperature, a PH value, and a concentration using a hydrothermal method, and embedding the first silver nanoparticle and the second silver nanoparticle into the electron transport layer using an electrospinning process comprise:
starting from an edge of the electron transport layer, embedding the spherical first silver nanoparticles, where a spacing parameter of the adjacent first silver nanoparticles is set to 6r; in a second time, embedding the rod-shaped second silver nanoparticles, starting at 4r from the edge of the electron transport layer, where a parameter of a distance between adjacent second silver nanoparticle particles is set to 6r, so that finally the Ag nanostructures with alternately embedded spheres and rods are formed; wherein r is a radius value of the spherical first nanoparticle.

18. A display panel, comprising an organic light-emitting device, a plurality of scan lines and a plurality of data lines, each of the organic light-emitting devices being connected to the respective scan line and the respective data line, the organic light-emitting device being formed on a glass substrate, wherein the organic light-emitting device comprises a first electrode, a second electrode, and an organic light-emitting layer disposed between the second electrode and the first electrode, wherein there is disposed a first light extraction layer between the first electrode and the glass substrate, wherein the first light extraction layer is formed of dielectric nanoparticles, and wherein a surface of the first light extraction layer facing towards the organic light-emitting layer has a rough surface.

19. The organic light-emitting device as recited in claim 18, wherein there is formed a second light extraction layer on a side of the glass substrate facing away from the organic light-emitting layer;
wherein the second light extraction layer comprises alternately arranged concave and convex portions; wherein he first light extraction layer is disposed in positions corresponding to the concave portions of the second light extraction layer and wherein portions of the first light extraction layer corresponding to the convex portions of the second light extraction layer are hollowed out.

20. The organic light-emitting device as recited in claim 18, wherein the dielectric nanoparticle is a silicon dioxide dielectric nanoparticle, wherein the entire first light extraction layer is fixed onto a side of the first electrode facing away from the organic light-emitting layer; wherein in the direction from the first electrode to the second electrode, the organic light-emitting layer comprises a hole injection layer, a hole transport layer, an organic light-emitting material layer, an electron transport layer, and an electron injection layer that are sequentially arranged:
wherein the first silver nanoparticle is spherical, the second silver nanoparticle is rod-shaped, and wherein the first silver nanoparticle and the second silver nanoparticle are alternately arranged at intervals.
